(19) United States
(12) Patent Application Publication
(10) Pub. No.: US 2008/0048294 A1
(43) Pub. Date: Feb. 28, 2008

(54) Semiconductor device with guard ring

(75) Inventor: Ryota Yamamoto, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/892,362

(22) Filed: Aug. 22, 2007

(30) Foreign Application Priority Data
Aug. 22, 2006 (JP) 2006-224912

(51) Int. Cl. H01L 29/00; H05K 9/00

(52) U.S. Cl. 257/536; 257/544; 361/816; 257/E23.192

(57) ABSTRACT

A semiconductor device includes a semiconductor substrate; a circuit; a guard ring; a power source line; and a contact. The semiconductor substrate has a first conductive type. The circuit is formed on the semiconductor substrate. The guard ring is formed on the semiconductor substrate such that the guard ring surrounds the circuit. The power source line supplies an electric power both the circuit and the guard ring. The contact is formed on the guard ring and connects the guard ring and the power source line. The guard ring is composed of a semiconductor having a second conductive type opposite to the first conductive type. The contact is placed in an opposite side of a noise source over the circuit.

### BACKGROUND OF THE INVENTION

1. Field of the Invention

The present invention relates to a semiconductor device, and more particularly relates to a semiconductor device that includes a guard ring for protecting a semiconductor circuit from external electric noise (hereafter, referred to as “noise”).

2. Description of Related Art

In a semiconductor device, it is required to protect a semiconductor circuit formed on a semiconductor substrate from external noise. For this reason, a conventional technique is known in which the periphery of the semiconductor circuit to be protected is surrounded with a conductor referred to as a guard ring. As a result, even if the external noise invades from peripheral environment, the outer guard ring protects the semiconductor circuit from suffering from the noise.

In relation to the foregoing explanation, the following technique is known.

Japanese Laid-Open Paten Application JP-P 2002-016227 A (corresponding to U.S. Pat. No. 6,555,884 B1) discloses an invention related to the semiconductor device.

The semiconductor device of the invention according to JP-P 2002-016227 A includes a circuit region, a first guard ring, a second guard ring, a first metal film pattern, a second metal film pattern, a first metal line and a second metal line. Here, the circuit region includes transistors formed on a semiconductor substrate. Also, the first guard ring is composed of an ion diffusion region formed to surround the circuit region. Moreover, the second guard ring is composed of an ion diffusion region of a high concentration formed to surround the first guard ring at a predetermined interval. Also, the first metal film pattern is formed opposite to the first guard ring through an insulating film and connected through a plurality of inter-layer wirings to the first guard ring. Moreover, the second metal film pattern is formed opposite to the second guard ring through an insulating film and connected through a plurality of inter-layer wirings to the second guard ring. Also, in the first metal line, the first metal film pattern is connected to an outer terminal to which a reference potential is applied. Moreover, in the second metal line, the second metal film pattern is connected to the outer terminal.

Japanese Laid-Open Paten Application JP-P 2000-049286 A discloses an invention related to the semiconductor device. The semiconductor device of the invention according to JP-P 2000-049286 A includes a semiconductor substrate, a first diffusion layer of a first conductive type, and a second diffusion layer of a second conductive type. Here, the semiconductor substrate includes an element formation area. The first diffusion layer of the first conductive type is formed around the element formation region in the semiconductor substrate, is connected to a first power source terminal, and shields the element formation region. The second diffusion layer of the second conductive type is formed inside the first diffusion layer, and is connected to a second power source terminal. The first diffusion layer and the second diffusion layer are biased opposite to each other, thereby forming a condenser.

We have now discovered facts which will be described below. FIGS. 1 and 2 are views showing examples of typical substrate noise guard rings. In FIG. 1, an N-well 102 as a guard ring is drawn around an analog circuit 101. The N-well 102 is connected to an independent power source 105 dedicated to the guard ring in a semiconductor substrate 100 through a backing wiring 104. In FIG. 2, a P+ diffusion layer 103 as a guard ring is drawn around an analog circuit 101. The P+ diffusion layer 103 is earthed to an independent ground 106 dedicated to the guard ring in a semiconductor substrate 100 through a backing wiring 104.

FIG. 3 is a view, which is the same as FIG. 1, showing a section line in the semiconductor substrate 100. FIG. 4 is a sectional view showing the semiconductor substrate 100 along the line A-A′ shown in FIG. 3. The typical semiconductor device includes the (P+) semiconductor substrate 100, the analog circuit 101, the N-well 102 (guard ring), the independent power source 105, a P-well 107, a N+ layer 108 and STIs (Shallow Trench Insulators) 109. In the typical technique, the guard ring requires the dedicated power source, and the semiconductor device requires one pad in order to introduce electric power from the power source. In addition, arrangement of a wiring is required in the circuit.

As a result, the design limitation and manufacturing cost of the semiconductor device are both increased.

Also, in the case of the guard ring of a deep N-well, the further mask and step are added, which further increases the design limitation and manufacturing cost.

In the invention according to JP-P 2002-016227 A, the guard rings of the diffusion layers are doubly formed around the circuit block. The guard rings are connected through the metal wirings to the pad, and the electrode is connected through a bonding wire to an external reference potential.

In this case, the formation of the pad dedicated to the guard rings is not preferable because this formation involves the increase in a chip area of a LSI.

Even if the pad of the guard rings is connected to a digital power source, the guard rings are noise sources. Further, even if the pad of the guard rings is connected to an analog power source, the guard rings are noise propagation paths. Thus, both of the cases have bad influence on the circuit.

In the invention according to JP-P 2000-049286 A, the P+ diffusion layer is formed inside the guard ring of the N-well. The potential of the N-well is pulled up to Vdd, and the P+ diffusion layer is earthed to the ground. A propagation of noise in the semiconductor substrate is suppressed in the thus-generated PN junction capacitance.

Also, in this case, even if a power source is connected to the guard rings in any way, the same problem as the invention according to the JP-P 2002-016227 A occurs.

### SUMMARY

The present invention seeks to solve one or more of the above problems, or to improve upon those problems at least in part. In one embodiment, a semiconductor device includes: a semiconductor substrate configured to have a first conductive type; a circuit configured to be formed on the semiconductor substrate; a guard ring configured to be formed on the semiconductor substrate such that the guard ring surrounds the circuit; a power source line configured to supply an electric power both the circuit and the guard ring; and a contact configured to be formed on the guard ring and connect the guard ring and the power source line. The guard ring is composed of a semiconductor having a second conductive type opposite to the first conductive type. The contact is placed in an opposite side of a noise source over the circuit.

In the present invention, a power source for a circuit targeted for the protection is used as a power source for a guard ring. As a result, one semiconductor pad for bringing in an electric power and the drawn-around wirings in the circuit can be reduced. These lead to advantage in the design limitation and manufacturing cost of the semiconductor circuit.

In the present invention, the guard ring itself is used as a resistance element. In particular, when a position of a noise source is specified, a contact is arranged at a position where a distance that the noise is transmitted through the guard ring can be set long. As a result, the resistance element for attenuating the noise can be reduced.

Moreover, as a result that the guard ring and a power source for an analog circuit portion are connected through the resistance element, even if the guard ring is in a floating state, charges resulting from the noise can be escaped to the power source for the analog circuit portion without any bad influence on the analog circuit.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1 and 2 are views showing examples of typical substrate noise guard rings;

FIG. 3 is a view, which is the same as FIG. 1, showing a section line in the semiconductor substrate;

FIG. 4 is a sectional view showing the semiconductor substrate along the line A-A′ shown in FIG. 3;

FIG. 5 is a block diagram showing a semiconductor chip in a first embodiment according to the present invention;

FIG. 6 is a view showing a semiconductor device in the first embodiment;

FIG. 7 is a conceptual view showing a semiconductor device in a second embodiment according to the present invention;

FIGS. 8 and 9 are plan views showing examples of the semiconductor device in the second embodiment;

FIG. 10 is a sectional view showing a part of the semiconductor device along the line B-B′ shown in FIG. 8, when the resistance element is the N-well resistance;

FIG. 11 is a sectional view showing a part of the semiconductor device along the line B-B′ shown in FIG. 8, when the resistance element is the polysilicon resistance;

FIG. 12 is a conceptual view showing an equivalent circuit of the semiconductor device in the second embodiment;

FIGS. 13 and 14 are views showing semiconductor devices in the third embodiment according to the present invention;

FIG. 15 is a sectional view showing a part of the semiconductor device along the line C-C′ shown in FIG. 13, when the resistance element is the N-well resistance; and

FIG. 16 is a sectional view showing a part of the semiconductor device along the line C-C′ shown in FIG. 13, when the resistance element 305 is the polysilicon resistance.

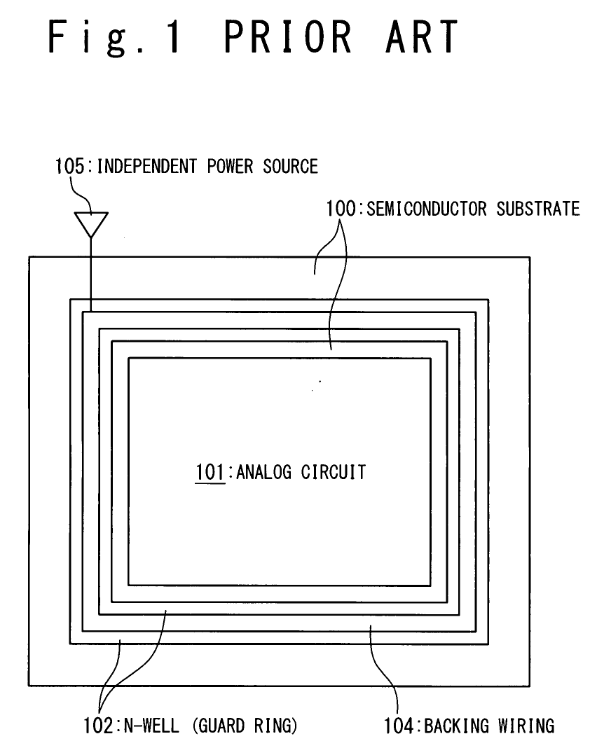

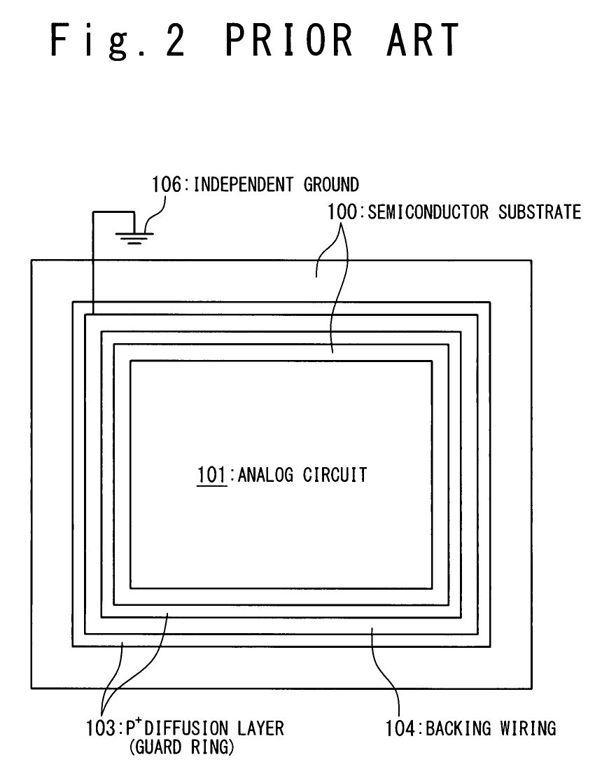

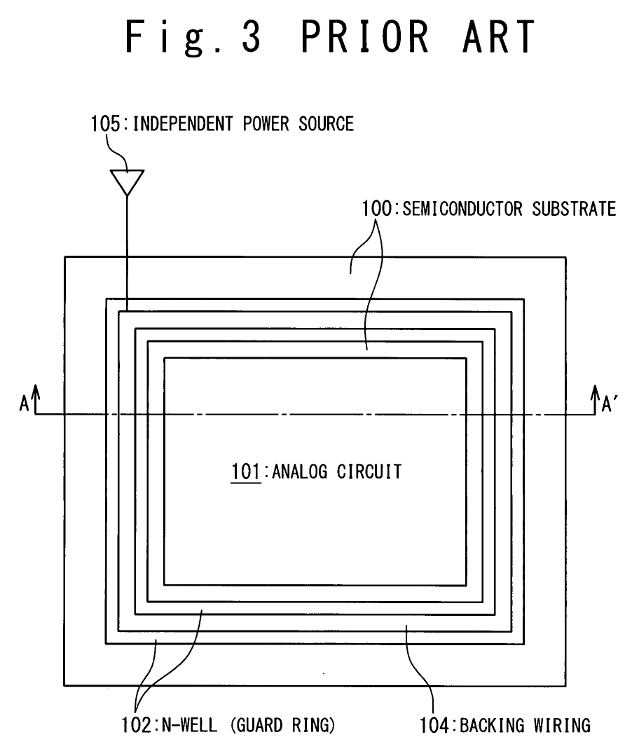

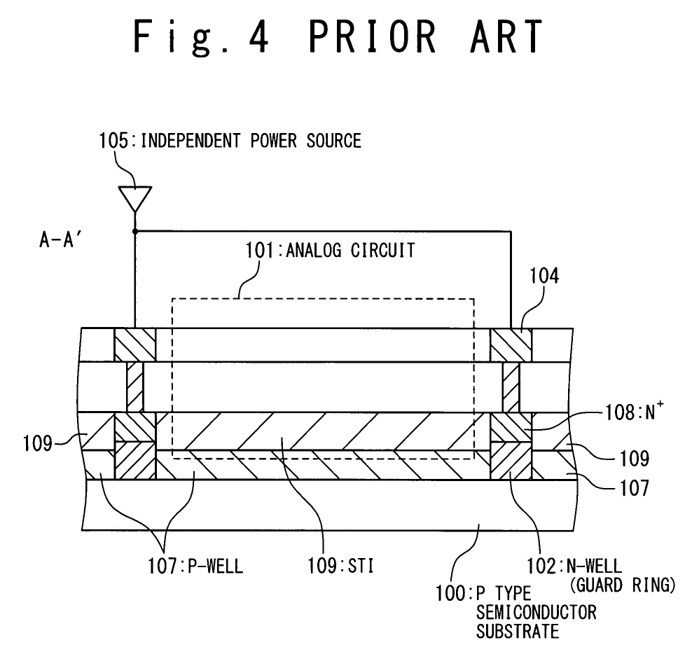

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

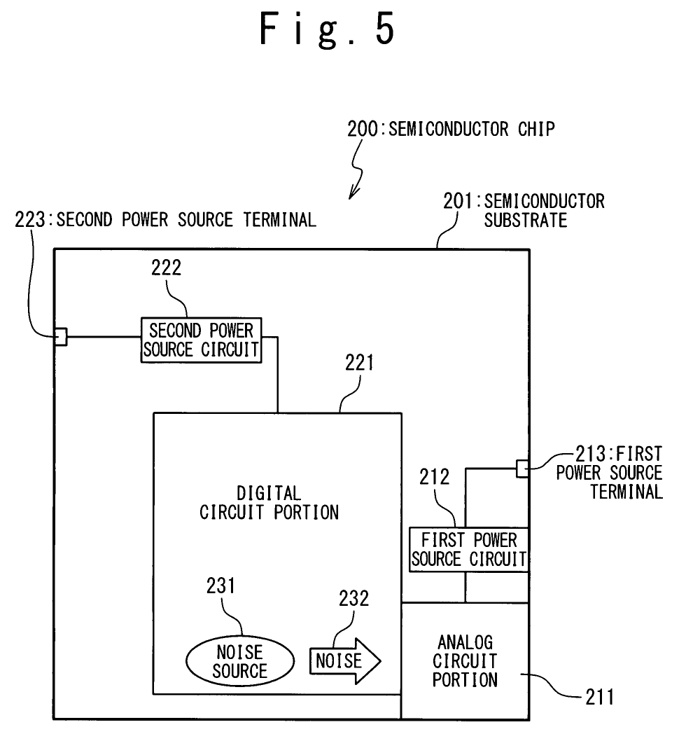

FIG. 5 is a block diagram showing a semiconductor chip 200 in the first embodiment according to the present invention. The semiconductor chip 200 includes a semiconductor substrate 201, an analog circuit portion 211, a first power source circuit 212, a first power source terminal 213, a digital circuit portion 221, a second power source circuit 222 and a second power source terminal 223.

The analog circuit portion 211 and the digital circuit portion 221 use power sources different from each other. The analog circuit portion 211 is connected through the first power source circuit 212 to the first power source terminal 213. Here, the first power source circuit 212 is a power source circuit for the analog circuit portion 211. The digital circuit portion 221 is connected through the second power source circuit 222 to the second power source terminal 223. Here, the second power source circuit 222 is a power source circuit for the digital circuit portion 221. Electric powers are supplied from outside the semiconductor chip 200 to the first power source terminal 213 and the second power source terminal 223, respectively.

The semiconductor chip 200, for example, includes a so-called PLL (Phase-Locked Loop). VCO (Voltage Control Oscillator) of the PLL and the like are included in the analog circuit portion 211, and a counter circuit of the PLL and the like are included in the digital circuit portion 221.

Typically, since a digital circuit treats an electric signal as a rectangular wave, the electric signal becomes a strong noise for an analog circuit. When they are formed on the same semiconductor substrate, an electric signal flowing in the digital circuit may be transmitted through the semiconductor substrate to the analog circuit.

In this embodiment, actually, noise is not generated by a particular part in the digital circuit portion 221. However, for an easily understandable explanation, a noise source 231 and a noise 232 are assumed. That is, it is represented that the digital circuit portion 221 has a noise source 231 which generates noise 232 with respect to the analog circuit portion 211.

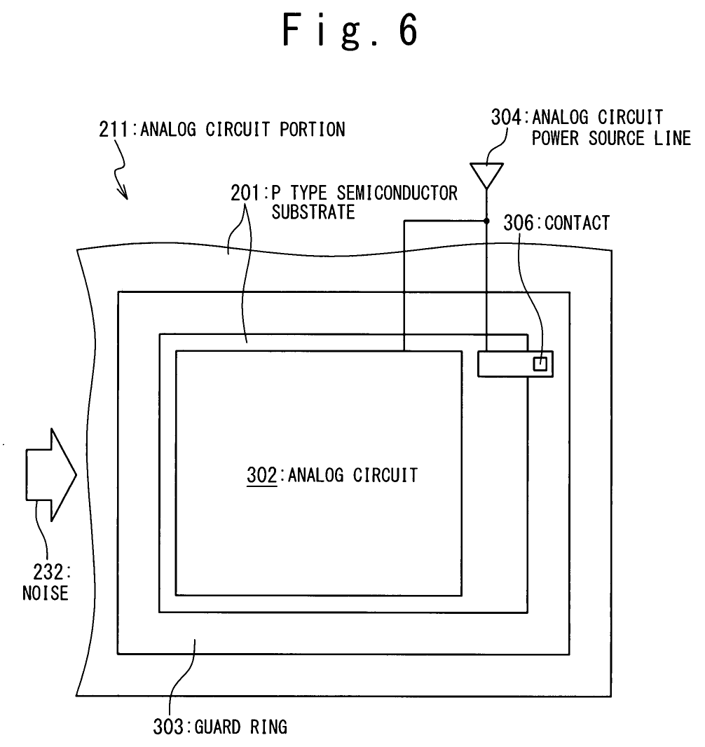

FIG. 6 is a view showing a semiconductor device in the first embodiment. The semiconductor device (hereinafter, also referred to as the semiconductor device 211) corresponds to the analog circuit portion 211 in the semiconductor chip 200. The semiconductor device 211 in this embodiment includes a semiconductor substrate 201, an analog circuit 302, a guard ring 303, an analog circuit power source line 304 and a contact 306.

The semiconductor substrate 201 in FIG. 6 is a part of the semiconductor substrate 201 in FIG. 5. Thus, the direction in which the noise 232 approaches the analog circuit portion 211 (semiconductor device 211) is determined.

Hereafter, this embodiment will be explained under assumption that the semiconductor substrate 201 is a P-type semiconductor, an N-well is used as the guard ring 303, and the analog circuit power source line 304 applies a positive voltage.

However, in this embodiment, a conductivity of the semiconductor and a polarity of the power source are naturally allowed to be made opposite. That is, even in the case that the semiconductor substrate 201 is a N-type semiconductor, a P-well is used as the guard ring 303, and the analog circuit power source line 304 is grounded, this embodiment is similarly operated.

The guard ring 303 is the N-well in which dopants are doped in silicon. Thus, the guard ring 303 has a characteristic of resistance.

In FIG. 5, the analog circuit portion 211, the first power source circuit 212, the digital circuit portion 221 and the second power source circuit 222 are formed on the semiconductor substrate 201.

In FIG. 6, the analog circuit 302 is formed on the semiconductor substrate 201. The guard ring 303 is similarly formed on the semiconductor substrate 201 so as to surround the analog circuit 302.

Also, the analog circuit power source line 304 is connected to both of the analog circuit 302 and the guard ring 303. Here, the guard ring 303 and the analog circuit power source line 304 are connected through the contact 306. The analog circuit power source line 304 is further connected to the first power source circuit 212.

The positive voltage from the analog circuit power source line 304 is applied to the guard ring 303, and the semiconductor substrate 201 is earthed. That is, the reversely-biased voltage is applied to the junction portion between the N-well serving as the guard ring 303 and the P-type semiconductor serving as the semiconductor substrate 201.

Thus, the reversely-biased voltage is applied to the junction portion between the guard ring 303 and the semiconductor substrate 201, and it operates as a junction capacitance 315. This is similar in the case that the conductivity of the semiconductor and the polarity of the power source are reverse, respectively.

In FIG. 5, the positional relation between the analog circuit portion 211 and the digital circuit portion 221, namely, the noise source 231 is fixed in the semiconductor chip 200. Thus, the direction in which the analog circuit portion 211 receives the noise 232 is fixed.

In FIG. 6, the contact 306 on the guard ring 303 is arranged such that a distance from an invasion route of the noise 232 over the analog circuit 302 is as long as possible. For example, the contact 306 is placed in a place opposite side of the guard ring 303 from to a noise source of the noise 232 over the analog circuit 302 is as long as possible.

When the noise source 231 in the digital circuit portion 221 generates the noise 232, the noise 232 is propagated through the semiconductor substrate 201. Actually, the propagation of the noise 232 implies a movement of electric charges, namely, a current.

The noise 232, when arriving at the analog circuit portion 211, is absorbed by the guard ring 303. The noise 232 absorbed by the guard ring 303 is attenuated by the N-well of the guard ring 303 serving as a resistance, while it is propagated through the guard ring 303.

The noise 232 propagated through the guard ring 303 exits from the guard ring 303 in the contact 306 and is absorbed by the analog circuit power source line 304. At this time, the noise 232 is desired to be propagated through the guard ring 303 of a longer distance and attenuated as much as possible. This is the reason why the contact 306 is arranged such that the distance from an invasion route of the noise 232 over the analog circuit 302 is set to be as long as possible.

### Second Embodiment

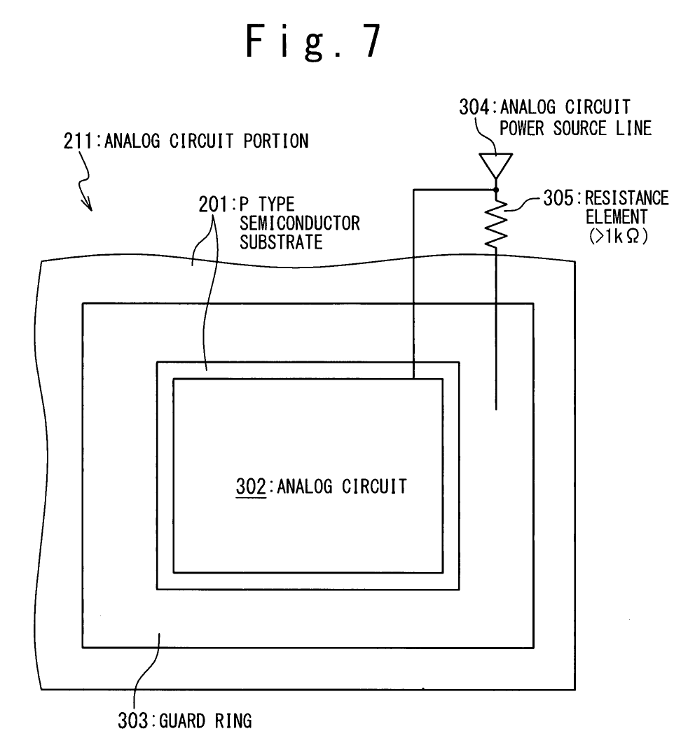

FIG. 7 is a conceptual view showing a semiconductor device in the second embodiment according to the present invention. The semiconductor device 211 corresponds to the analog circuit portion 211 in the semiconductor chip 200. The analog circuit portion 211 in the second embodiment is equivalent to a configuration in which the resistance element 305 is added to the analog circuit portion 211 in the first embodiment. That is, the analog circuit portion 211 in this embodiment includes a resistance element 305, in addition to the semiconductor substrate 201, the analog circuit 302, the guard ring 303 and the analog circuit power source line 304. Here, FIG. 7, which is the conceptual view, does not show the contact 306 to connect the guard ring 303 and the resistance element 305.

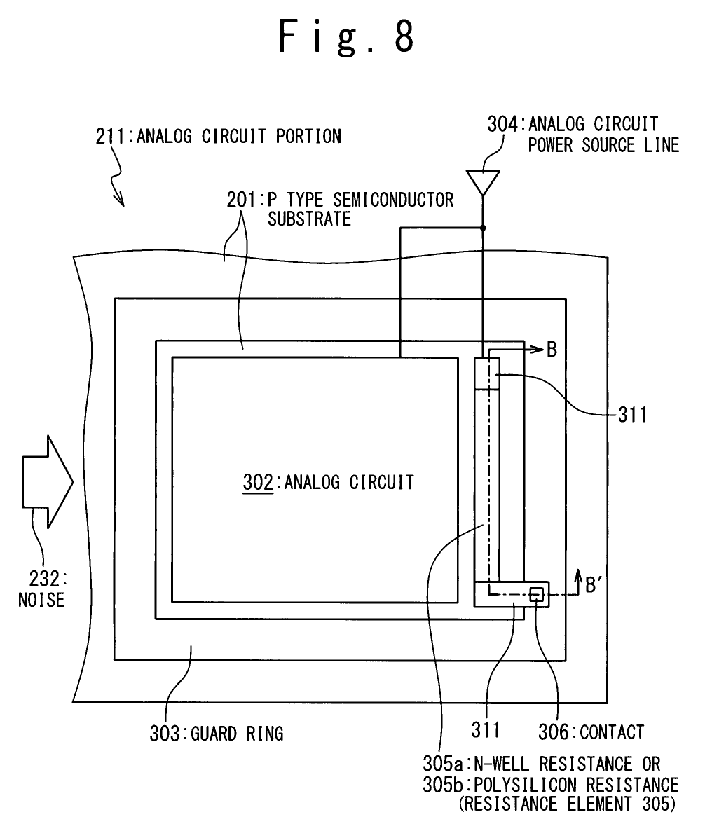

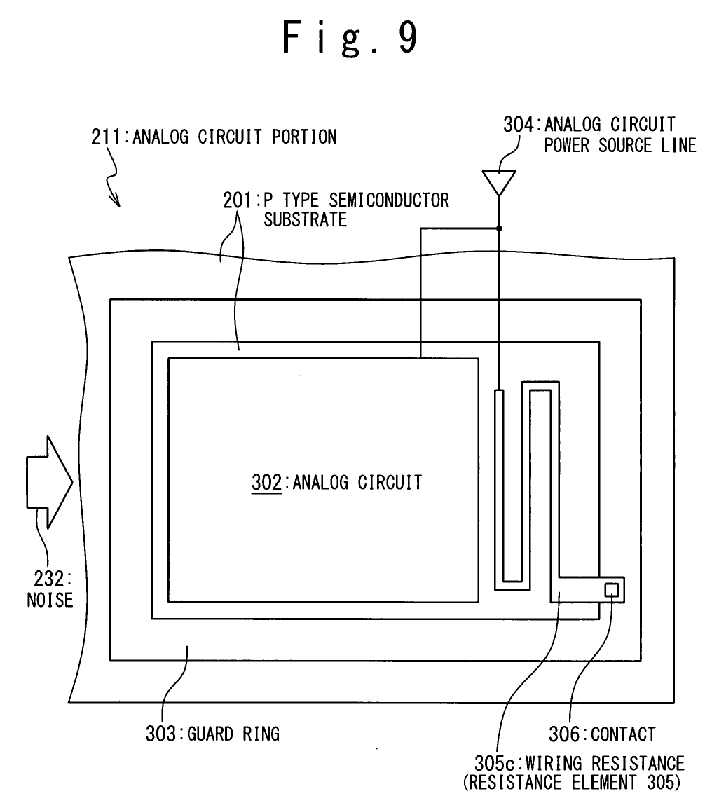

FIGS. 8 and 9 are plan views showing examples of the semiconductor device in the second embodiment. The resistance element 305 in this embodiment may be an N-well resistance 305a or a polysilicon resistance 305b that is formed on the semiconductor substrate 201 as shown in FIG. 8, or may be a wiring resistance 305c that is drawn around as shown in FIG. 9.

FIG. 8 shows the semiconductor device 211 when the resistance element 305 is the N-well resistance 305a or the polysilicon resistance 305b, in this embodiment. That is, similarly to FIG. 6 in the first embodiment, the semiconductor device 211 includes the semiconductor substrate 201, the analog circuit 302, the guard ring 303, the analog circuit power source line 304 and the contact 306. Also, the semiconductor device 211 further includes the N-well resistance 305a or polysilicon resistance 305b to connect the guard ring 303 and the analog circuit power source 304.

FIG. 9 shows the semiconductor device 211 in which the resistance element 305 is the drawn-around wiring 305c, in this embodiment. That is, similarly to FIG. 6 in the first embodiment, the semiconductor device 211 includes the semiconductor substrate 201, the analog circuit 302, the guard ring 303, the analog circuit power source line 304 and the contact 306. Also, the semiconductor device 211 further includes the drawn-around wiring 305c to connect the guard ring 303 and the analog circuit power source 304.

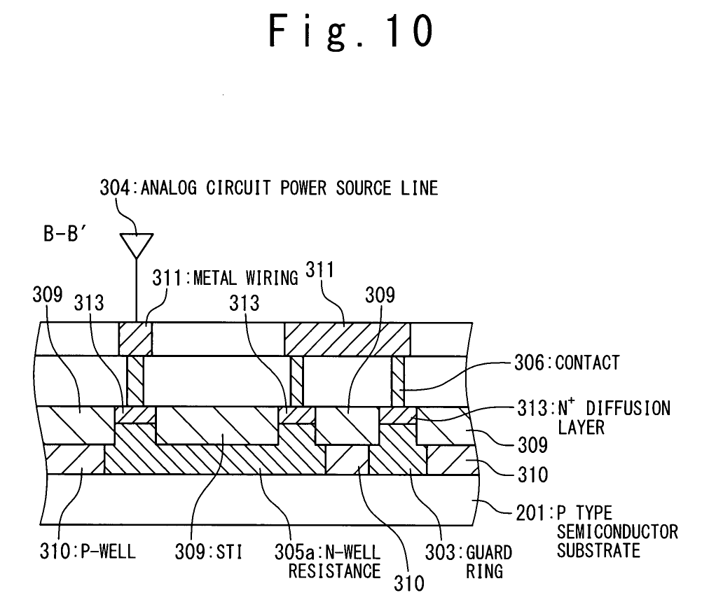

FIG. 10 is a sectional view showing a part of the semiconductor device along the line B-B′ shown in FIG. 8, when the resistance element 305 is the N-well resistance 305a. The analog circuit portion 211 in this embodiment includes: the semiconductor substrate 201 in the lowest layer; a P-well 310 and the guard ring 303 of the N-well and the N-well resistance 305a in a layer located on the lowest layer; and an STI (Shallow Trench Insulator) 309 and an N+ diffusion layer 313 in a layer further located thereon. Moreover, the contact 306 is connected to the upper portion of the N+ diffusion layer 313, the metal wiring 311 is connected to the upper portion of the contact 306, and the analog circuit power source line 304 is connected to the metal wiring 311, respectively.

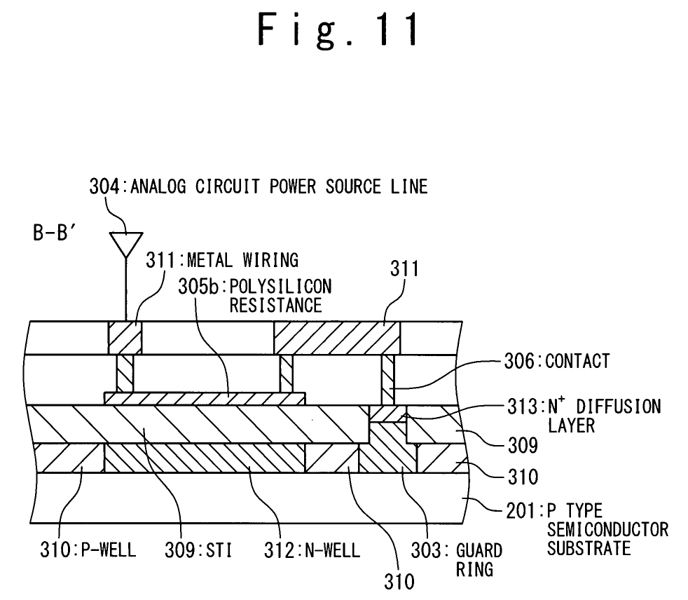

FIG. 11 is a sectional view showing a part of the semiconductor device along the line B-B′ shown in FIG. 8, when the resistance element 305 is the polysilicon resistance 305b. The analog circuit portion 211 in this embodiment includes: the semiconductor substrate 201 in the lowest layer; a P-well 310, a N-well 312 and the guard ring 303 of the N-well in a layer located on the lowest layer, and the STI (shallow Trench Insulator) 309 and the N+ diffusion layer 313 in a layer further located thereon. Moreover, the contact 306 is connected to the upper portion of the N+ diffusion layer 313, and the polysilicon resistance 305b is placed on the upper portion of the STI, respectively. Finally, the metal wiring 311 is connected to the upper portion of the contact 306 and the polysilicon resistance 305b, and the analog circuit power source line 304 is connected to the metal wiring 311, respectively.

In this embodiment, the N-well resistance 305a is connected between the contact 306 in the first embodiment and the analog circuit power source line 304. The resistance element 305 is formed inside the guard ring 303, similarly to the analog circuit 302. Here, a resistance value of the N-well resistance 305a is desired to be high (specifically, for example, several 10 to 100 kΩ).

In this embodiment, since the N-well resistance 305a is added, the noise is further reduced as compared with the first embodiment.

Also, similarly to the first embodiment, even in this embodiment, the junction portion between the guard ring 303 and the semiconductor substrate 201 operates as the junction capacitance 315 because the reversely-biased voltage is applied thereto.

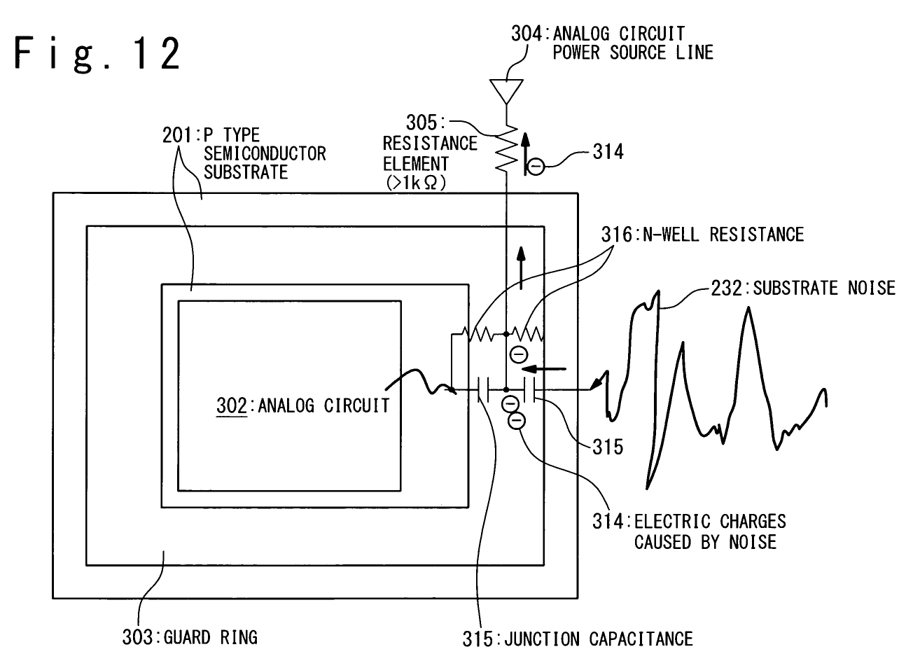

FIG. 12 is a conceptual view showing an equivalent circuit of the semiconductor device in the second embodiment. In this embodiment, the resistance element 305 (e.g. the N-well resistance 305a) is further added to the first embodiment, and its equivalent circuit is as shown in FIG. 12.

For the noise 232 trying to invade the analog circuit 302, an N-well resistance 316 (a resistance element of the guard ring 303 of the N-well) and the junction capacitance 315 in the NP junction between the semiconductor substrate 201 and the guard ring 303 constitute the high pass filter. That is, this high pass filter can protect the analog circuit 302 from the low frequency components of the noise 232.

Here, the resistance element 305 having the high resistance value is connected between the guard ring 303 and the analog circuit power source line 304. Thus, the potential of the guard ring 303 is in the substantially floating state in view of the alternate current manner.

At the time of the floating sate of the guard ring 303, when the potential of the semiconductor substrate 201 is changed, electric charges 314 may flow into the guard ring 303 from the semiconductor substrate 201. In this case, the potential of the guard ring 303 is decreased, which causes a trouble in the operation of the analog circuit portion 211.

However, in this embodiment, the guard ring 303 and the analog circuit power source line 304 are connected through the resistance element 305. For this reason, the electric charges 314 flowing into the guard ring 303 are released through the resistance element 305 to the analog circuit power source line 304, while the first power source circuit 212 is separated from the guard ring 303 in the alternate current manner by the resistance element 305.

At this time, when a resistance value of the power source wiring has, for example, about several Ω to several 10Ω, a resistance value of the resistance element 305 (e.g. the N-well resistor 305a) is desired to be several 10 kΩ or more.

Here, the fact that the noise electric charges 314 are released from the guard ring 303 in the floating state through the resistance element 305 of several 10 kΩ to the analog circuit power source line 304 is effective not only in this embodiment but also in the third embodiment, which will be described below.

### Third Embodiment

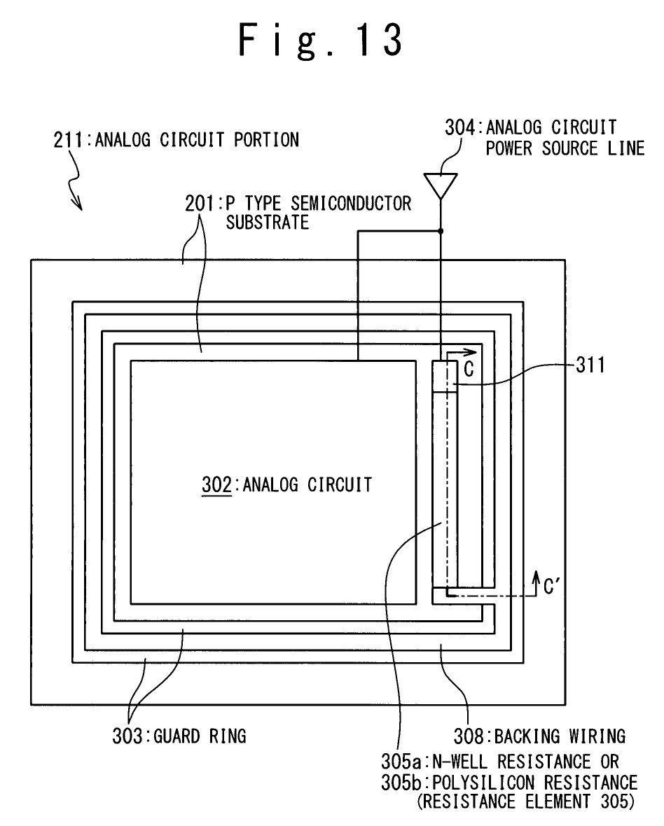

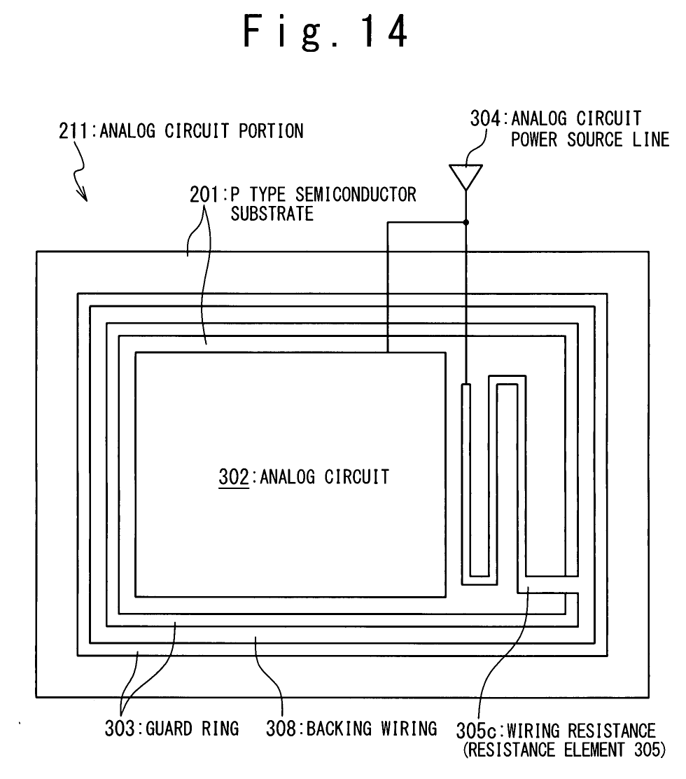

FIGS. 13 and 14 are views showing semiconductor devices in the third embodiment according to the present invention. The semiconductor device 211 corresponds to the analog circuit portion 211 in the semiconductor chip 200. The third embodiment is equivalent to a configuration in which a backing wiring 308 is added to the guard ring 303 in the second embodiment. Thus, the analog circuit portion 211 in this embodiment includes the semiconductor substrate 201, the analog circuit 302, the guard ring 303, the analog circuit power source line 304 and the resistance element 305, and further includes the backing wiring 308. However, FIGS. 13 and 14 do not show a plurality of contacts 306 to connect the guard ring 303 and the backing wiring 308.

FIG. 13 shows a case that the resistance element 305 is the N-well resistance 305a or polysilicon resistance 305b, in this embodiment.

FIG. 14 shows a case that the resistance element 305 is the wiring resistance 305c, in this embodiment.

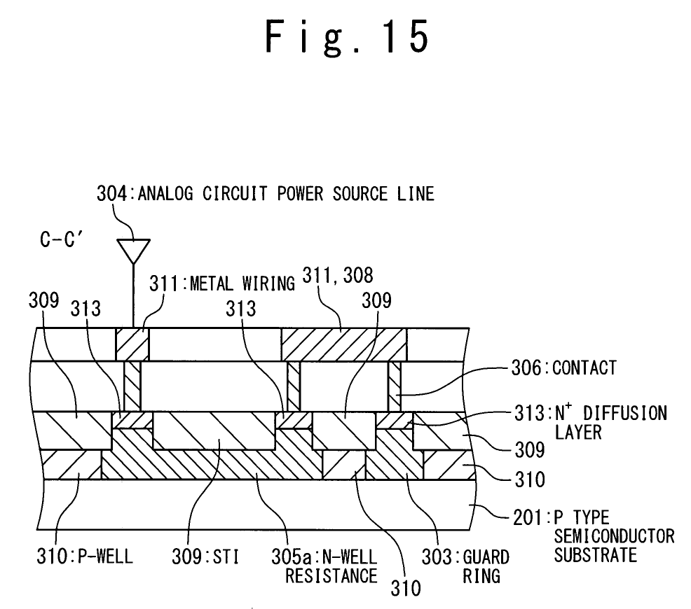

FIG. 15 is a sectional view showing a part of the semiconductor device along the line C-C′ shown in FIG. 13, when the resistance element 305 is the N-well resistance 305a. The analog circuit portion 211 in this embodiment includes: the semiconductor substrate 201 in the lowest layer; a P-well 310 and the guard ring 303 of the N-well and the N-well resistance 305a in a layer located on the lowest layer; and the STI (Shallow Trench Insulator) 309 and the N+ diffusion layer 313 in a layer further located thereon. Moreover, the contact 306 is connected to the upper portion of the N+ diffusion layer 313, the metal wiring 311 including the backing wiring 308 is connected to the upper portion of the contact 306, and the analog circuit power source 304 is connected to the metal wiring 311, respectively.

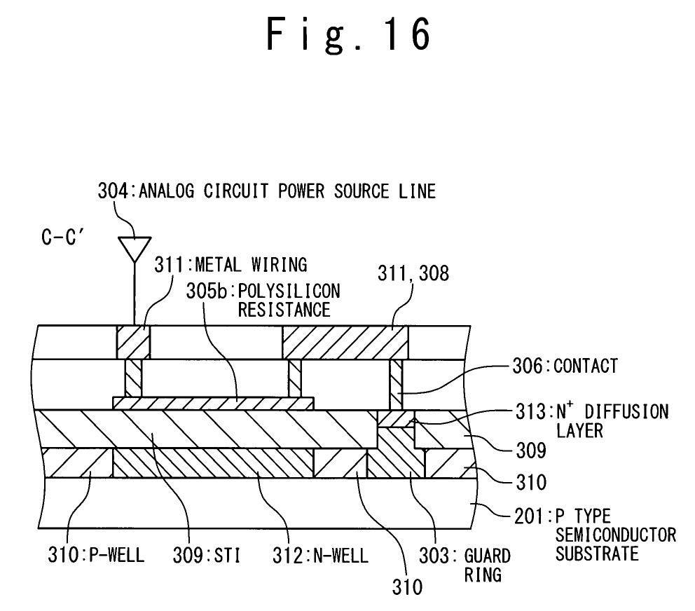

FIG. 16 is a sectional view showing a part of the semiconductor device along the line C-C′ shown in FIG. 13, when the resistance element 305 is the polysilicon resistance 305b. The analog circuit portion 211 in this embodiment includes: the semiconductor substrate 201 in the lowest layer; a P-well 310 and the guard ring 303 of the N-well and the polysilicon resistor 305b located in a layer on the lowest layer, and the STI (Shallow Trench Insulator) 309 and the N+ diffusion layer 313 in a layer further located thereon. Moreover, the contact 306 is connected to the upper portion of the N+ diffusion layer 313, and the metal wiring 311 including the backing wiring 308 is connected to the upper portion of the contact 306, and the analog circuit power source line 304 is connected to the metal wiring 311, respectively.

The reason why the backing wiring 308 is added is to be able to similarly absorb the noise 232 whichever direction the noise 232 invades the analog circuit portion 211 from. That is, since the backing wiring 308 is added, potentials of all places in the guard ring 303 become constant. The noise 232 absorbed in the guard ring 303 is attenuated by the resistance element 305.

Here, the junction capacitance 315 in the NP junction between the guard ring 303 and the semiconductor substrate 201 is not affected by the backing wiring 308. Thus, the high pass filter including the junction capacitance 315 and the resistance element 305, further attenuates the low frequency components of the noise 232.

Also, the resistance element 305 having the high resistance value is connected between the guard ring 303 and the analog circuit power source line 304. Thus, the potential of the guard ring 303 is in the substantially floating state in view of the alternate current manner. However, the noise electric charges 314 are released from the guard ring 303 in the floating state through the resistance element 305 of several 10 kΩ to the analog circuit power source line 304. Thus, any trouble does not occur in the operations of the analog circuit 302.

The present invention includes a method of protecting a semiconductor circuit from noise. The method includes steps (a) to (c). The step (a) is a step of absorbing first electric charges as noise moving through a semiconductor substrate, by a guard ring which surrounds a circuit formed on said semiconductor substrate. The step (b) is a step of attenuating a first electric power based on said first electric charges, by a route which includes a resistance element and connects a power source line supplying second electric power to said circuit and said guard ring such that said first electric power passes through said route. The step (c) is a step of absorbing said first electric power which is attenuated by said route, by said power source line.

In the present invention, the semiconductor chip 200 including the analog circuit portion 211 can be deemed to be the semiconductor device.

It is apparent that the present invention is not limited to the above embodiment, but may be modified and changed without departing from the scope and spirit of the invention.

What is claimed is:

1. A semiconductor device comprising:
a semiconductor substrate configured to have a first conductive type;
a circuit configured to be formed on said semiconductor substrate;
a guard ring configured to be formed on said semiconductor substrate such that said guard ring surrounds said circuit;
a power source line configured to supply an electric power both said circuit and said guard ring; and
a contact configured to be formed on said guard ring and connect said guard ring and said power source line,
wherein said guard ring is composed of a semiconductor having a second conductive type opposite to said first conductive type, and
said contact is placed in an opposite side of a noise source over said circuit.

2. The semiconductor device according to claim 1, wherein said first conductive type is a P type,
said second conductive type is a N type, and
a positive voltage is applied to said power source line.

3. The semiconductor device according to claim 1, wherein said first conductive type is an N type,
said second conductive type is a P type, and
said power source line is earthed.

4. The semiconductor device according to claim 1, further comprising:
a resistance element configured to be formed on said semiconductor substrate,
wherein said contact and said power source line is connected to each other through said resistance element.

5. The semiconductor device according to claim 4, wherein said resistance element is a polysilicon resistance formed inside said guard ring.

6. The semiconductor device according to claim 1, wherein said resistance element is an N-well formed inside said guard ring.

7. The semiconductor device according to claim 4, wherein said resistance element is a wiring formed on said semiconductor substrate, and
said wiring drawn around an inside area of said guard ring connects said contact and said power source line.

8. The semiconductor device according to claim 1, further comprising:
a digital circuit portion configured to be formed on said semiconductor substrate and provided outside said guard ring.

9. A semiconductor device comprising:
a semiconductor substrate configured to have a first conductive type;
a circuit configured to be formed on said semiconductor substrate;
a guard ring configured to be formed on said semiconductor substrate such that said guard ring surrounds said circuit;
a power source line configured to be connected to both said circuit and said guard ring;
a contact configured to connect said guard ring and said power source line; and
a resistance element configured to connect said contact and said power source line,
wherein said guard ring is composed of a semiconductor having a second conductive type opposite to said first conductive type.

10. The semiconductor device according to claim 9, wherein said first conductive type is a P type,
said second conductive type is a N type, and
a positive voltage is applied to said power source line.

11. The semiconductor device according to claim 9, wherein said first conductive type is an N type,
said second conductive type is a P type, and
said power source line is earthed.

12. The semiconductor device according to claim 9, further comprising:
a backing wiring configured to be formed on said guard ring.

13. The semiconductor device according to claim 12, wherein said resistance element is a polysilicon resistance formed inside said guard ring.

14. The semiconductor device according to claim 9, wherein said resistance element is an N-well formed inside said guard ring.

15. The semiconductor device according to claim 12, wherein said resistance element is a wiring formed inside said guard ring, and
said wiring drawn around an inside area of said guard ring connects said contact and said power source line.

16. The semiconductor device according to claim 9, further comprising:
a digital circuit portion configured to be formed on said semiconductor substrate and provided outside said guard ring.

17. A method of protecting a semiconductor circuit from noise, comprising:
(a) absorbing first electric charges as noise moving through a semiconductor substrate, by a guard ring which surrounds a circuit formed on said semiconductor substrate;
(b) attenuating an first electric power based on said first electric charges, by a route which includes a resistance element and connects a power source line supplying second electric power to said circuit and said guard ring such that said first electric power passes through said route; and
(c) absorbing said first electric power which is attenuated by said route, by said power source line.
